(19) United States
(12) Patent Application Publication
(10) Pub. No.: US 2026/0040450 A1
(43) Pub. Date: Feb. 5, 2026

(54) INTERPOSER AND PREPARATION METHOD THEREOF, AND A SYSTEM-IN-PACKAGE STRUCTURE

(71) Applicant: Universal Global Technology (Shanghai) Co., Ltd., Shanghai (CN)

(72) Inventors: Yingfeng Hua, Shanghai (CN); Dequan Liu, Shanghai (CN); Qihui Wang, Shanghai (CN); Gaohang Wang, Shanghai (CN); Silang Chen, Shanghai (CN)

(73) Assignee: Universal Global Technology (Shanghai) Co., Ltd., Shanghai (CN)

(21) Appl. No.: 19/020,117

(22) Filed: Jan. 14, 2025

(30) Foreign Application Priority Data
Jul. 31, 2024 (CN) 202411045116.7

(51) Int. Cl. H05K 1/14; H05K 1/11; H05K 1/18; H05K 3/00

(52) U.S. Cl. CPC H05K 1/144; H05K 1/115; H05K 1/181; H05K 3/0026; H05K 3/0044; H05K 2201/10378; H05K 2203/107

(57) ABSTRACT

An interposer and preparation method thereof, and a system-in-package structure are disclosed. The interposer comprises: a vertical body and a horizontal branch, wherein the vertical body and the horizontal branch form a T-shaped structure; the vertical body comprises a bottom copper foil layer and a first insulating layer, wherein the bottom copper foil layer is provided with several first pads; the horizontal branch comprises a blocking copper foil layer, a second insulating layer and a top copper foil layer, wherein the top copper foil layer is provided with second pads corresponding to the first pads; each first pad position is provided with a via penetrating the first insulating layer and the blocking copper foil layer, and the first pad is electrically connected to the corresponding second pad through the via. The interposer realizes a fan-out connection function, and saves the space occupied on the motherboard due to its T-shaped structure.

### FIELD OF THE DISCLOSURE

The present application relates to a technical field of semiconductor technology, and particularly to an interposer and preparation method thereof, and a system-in-package structure.

### BACKGROUND

Due to product functional requirements, the current SIP (system-in-package) process requires part of the motherboard circuit to be fanned out of the molding package for subsequent testing or hot bar process. For example, some circuit monitoring points on the motherboard are led to the surface of the molding package for subsequent testing.

To realize the above functions, an interposer is currently used as a fan-out intermediate connector in the SMT assembly process of the SIP. The interposer is designed to be a top-down symmetrical structure, as shown in FIG. 4. The left side is a top view of the interposer, which has 6 rows and 10 columns of pads. The right side is a cross-sectional view of the interposer, in which the upper pad 1 is symmetrical to the lower pad 2 and is electrically connected through a via.

The problems with this process are as follows:

Due to the limitations imposed by the size of the pads and the spacing between pads on the upper surface of the interposer as dictated by subsequent processes or test point size requirements, it is not possible to reduce their dimensions. The currently used interposer has a columnar structure, with symmetrical design between the bottom pad and the top pad. As a result, the size and spacing of the bottom pads cannot be reduced. This type of interposer, when assembled onto the motherboard, occupies a larger layout space, thereby affecting the placement of components on the motherboard.

### SUMMARY OF THE INVENTION

One of the purposes of the present invention is to provide an interposer and a method for preparing the interposer and a system-level packaging structure, so as to solve the problems existing in the prior art.

The technical solution provided by the present invention is as follows:

An interposer comprises: a vertical body and a horizontal branch, wherein the horizontal branch extends outward from a top of the vertical body; the top of the vertical body contacts a bottom of the horizontal branch to form a T-shaped structure;
the vertical body comprises a bottom copper foil layer and a first insulating layer in order from bottom to top, and a plurality of first pads are provided on the bottom copper foil layer;
the horizontal branch comprises a blocking copper foil layer, a second insulating layer and a top copper foil layer in order from bottom to top; the top copper foil layer is provided with second pads corresponding to the first pads one by one; an area of a bottom of the vertical body is smaller than an area of a top of the horizontal branch;
a via penetrating the first insulating layer and the blocking copper foil layer is provided at each first pad position, and one first pad is electrically connected to one corresponding second pad located on the top copper foil layer through the via.

In some embodiments, the horizontal branch further comprises N first copper foil layers between the blocking copper foil layer and the top copper foil layer, where N>=1; and second insulating layers are provided between adjacent copper foil layers from the blocking copper foil layer to the top copper foil layer;
one first pad is electrically connected to one corresponding second pad located on the top copper foil layer through the via, comprising: the first pad is electrically connected to the first copper foil layer through the via, and is electrically connected to the corresponding second pad located on the top copper foil layer through the first copper foil layer.

In some embodiments, a height of the first insulating layer is greater than a height of the horizontal branches.

The present application also provides a preparation method for an interposer, comprising:
manufacturing a printed circuit board with multi layers, wherein the PCB comprises, from bottom to top, a bottom copper foil layer, a first insulating layer, a blocking copper foil layer and a top copper foil layer, wherein a second insulating layer is provided between the blocking copper foil layer and the top copper foil layer; a plurality of first pad groups are provided on the bottom copper foil layer, wherein the first pad group comprises a plurality of first pads; a plurality of second pad groups corresponding to the first pad groups are provided on the top copper foil layer, wherein the second pad group comprises second pads corresponding to the first pads one by one; an area of the first pad group is smaller than an area of the second pad group; a via penetrating the first insulating layer and the blocking copper foil layer is provided at each first pad position, wherein one first pad is electrically connected to one corresponding second pad located on the top copper foil layer through the via;
removing the first insulating layer between adjacent first pad groups on the PCB;
cutting the PCB along a center line between adjacent second pad groups to obtain an interposer after cutting.

In some embodiments, the step of one first pad is electrically connected to one corresponding second pad located on the top copper foil layer through the via, comprising: the first pad is electrically connected to the top copper foil layer through the via, and is electrically connected to the corresponding second pad located on the top copper foil layer through the top copper foil layer.

In some embodiments, the PCB further comprises N first copper foil layers between the blocking copper foil layer and the top copper foil layer, where N>=1; and second insulating layers are provided between adjacent copper foil layers from the blocking copper foil layer to the top copper foil layer;
the step of one first pad is electrically connected to one corresponding second pad located on the top copper foil layer through the via, comprising:
the first pad is electrically connected to the top copper foil layer through the via, and is electrically connected to the corresponding second pad located on the top copper foil layer through the top copper foil layer.

In some embodiments, the first pad group is composed of first pads in X rows and Y columns;
the PCB further comprises N first copper foil layers between the blocking copper foil layer and the top copper foil layer, wherein N is equal to a result of rounding up a quotient obtained by dividing a minimum value of X and Y by 2.

In some embodiments, removing the first insulating layer between adjacent first pad groups on the PCB by laser or etching.

The present application also provides a system-in-package structure, comprising:
motherboard;
electronic components, which are installed on a surface of the motherboard;
an interposer according to any one of the above embodiments is installed on the surface of the motherboard through its vertical body;
a molding package, which encapsulates the electronic components and the interposer, and a top of a horizontal branch of the interposer is exposed from the molding package.

In some embodiments, at least one electronic component is installed in at least one gap formed by the horizontal branch of the interposer, the vertical body and the motherboard.

The interposer and preparation method thereof, and a system-in-package structure provided by the present application can at least bring the following beneficial effects: the interposer provided by the present application realizes the fan-out connection function, has a T-shaped structure, saves the space occupied on the motherboard, and improves the space utilization of the motherboard.

### BRIEF DESCRIPTION OF THE DRAWINGS

The preferred implementation scheme will be described below in a clear and understandable manner with reference to the accompanying drawings to further illustrate the above-mentioned characteristics, technical features, advantages and implementation methods of an interposer and preparation method thereof, and a system-in-package structure.

FIG. 1 is a schematic structural diagram of an interposer according to an embodiment of the present application;

FIG. 2 is a schematic top view of the interposer shown in FIG. 1;

FIG. 3 is a schematic structural diagram of an interposer according to another embodiment of the present application;

FIG. 4 is a schematic diagram of the structure of an existing interposer;

FIG. 5 is a flow chart of a preparation method for an interposer according to an embodiment of the present application;

FIGS. 6-7 are process flow diagrams for preparing an interposer according to an embodiment of the present application;

FIG. 8 is a schematic structural diagram of a system-in-package structure according to an embodiment of the present application.

### DESCRIPTION OF THE ILLUSTRATED EMBODIMENTS

To more clearly illustrate the embodiments of the present application or the technical solutions in the prior art, the specific implementation methods of the present application will be described below with reference to the accompanying drawings. Obviously, the accompanying drawings described below are only some embodiments of the present application. For ordinary technical persons in this field, other drawings and other implementation methods can be obtained based on these drawings without creative work.

To simplify the drawings, only the parts related to the present application are schematically shown in each figure, and they do not represent the actual structure of products. In addition, to simplify the drawings and facilitate understanding, in some figures, only one of the parts with a same structure or function is schematically drawn or marked. In this specification, “one” not only means “only one”, but also may mean “more than one”.

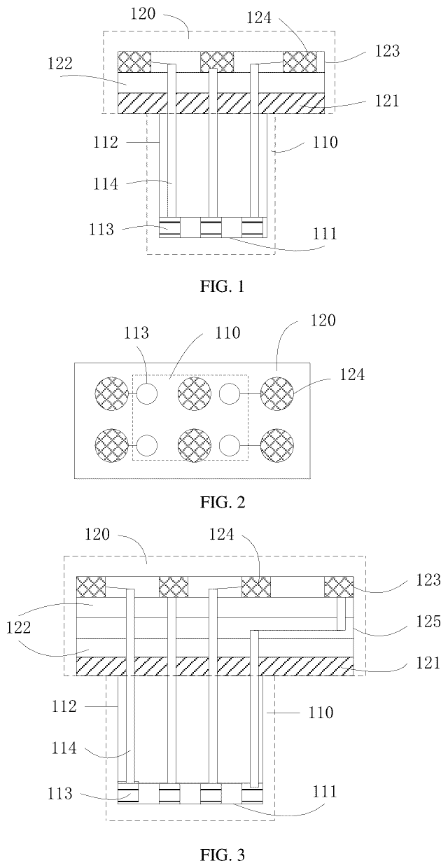

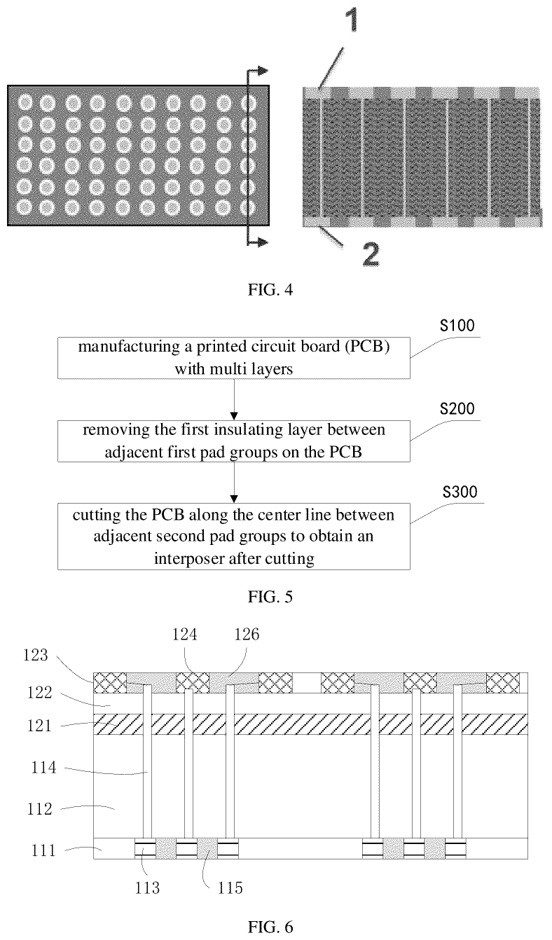

In one embodiment of the present application, as shown in FIG. 1, an interposer 100 comprises:

A vertical body 110 and a horizontal branch 120, the horizontal branch extends outward from the top of the vertical body; the top of the vertical body contacts the bottom of the horizontal branch to form a T-shaped structure.

The vertical body comprises a bottom copper foil layer 111 and a first insulating layer 112 in sequence from bottom to top, and there are and only have a plurality of first pads 113 on the bottom copper foil layer.

The horizontal branch comprises a blocking copper foil layer 121, a second insulating layer 122 and a top copper foil layer 123 in order from the bottom to the top. The blocking copper foil layer 121 is adjacent to the first insulating layer, and is used to prevent the removal process from crossing the boundary when a portion of the first insulating layer 112 is removed during the preparation of the interposer 100. The second insulating layer is provided between the blocking copper foil layer 121 and the top copper foil layer 123, and is used to electrically isolate adjacent copper foil layers.

The top copper foil layer is provided with second pads 124 corresponding to the first pads one by one, so the number of first pads is equal to the number of second pads, and for each first pad there is a corresponding second pad.

The area of the bottom of the vertical body is smaller than the area of the top of the horizontal branch. The bottom copper foil layer 111 is used to place the first pad, and the top copper foil layer 123 is used to place the second pad, and the number of first pads is equal to the number of second pads. Therefore, this requires that the size of the first pad is smaller than the size of the second pad, and/or the spacing between adjacent first pads is smaller than the spacing between adjacent second pads.

A via 114 penetrating the first insulating layer 112 and the blocking copper foil layer 121 is provided at each first pad position, and one first pad is electrically connected to one corresponding second pad located on the top copper foil layer through the via.

The via 114 comprises a via body, the inner wall of which has been covered with metal (such as electroplated copper), and there is a safety gap between the via body and the copper foil layer that does not need electrical connection, and the via body is electrically connected to the copper foil layer that has electrical connection through the signal routing of the layer, so the first pad connected to the via 114 can achieve cross-layer electrical connection through the via 114. As shown in FIG. 1, the via 114 penetrates the first insulating layer 112, the blocking copper foil layer 121 and the second insulating layer 122 to the top copper foil layer, wherein some first pads are directly electrically connected to the corresponding second pads through the vias, and some first pads are electrically connected to the top copper foil layer through the vias, and then electrically connected to the corresponding second pads through the signal routing. FIG. 2 is the corresponding top view.

FIG. 1 is only an example of realizing the electrical connection between first pads and second pads. If the via 114 at the first pad position extends to the top copper foil layer without conflicting with other pads (for example, does not overlap with other pads, and the spacing with other pads is not less than the safety range, etc.), the via can be extended to the top copper foil layer as shown in FIG. 1, and then the signal routing of the top copper foil layer realizes the electrical connection between the first pad and the corresponding second pad.

If the via 114 at the first pad position extends to the top copper foil layer and conflicts with other pads, a first copper foil layer 125 can be added between the blocking copper foil layer and the top copper foil layer, and second insulating layers 122 can be added between the first copper foil layer and the adjacent copper foil layer. The via 114 can be extended to the first copper foil layer, and electrically connected to the corresponding second pad located at the top copper foil layer through the first copper foil layer. As shown in FIG. 3, the via 114 at the rightmost first pad position belongs to the above situation. It is extended to the first copper foil layer, and the corresponding second pad is electrically connected to the first copper foil layer through the via, and then the signal routing on the first copper foil layer realizes the electrical connection between the first pad and the corresponding second pad; other first pads can realize the electrical connection with the corresponding second pad in the manner shown in FIG. 1. Some, such as the leftmost first pad, can also extend the via 114 to the first copper foil layer, and realize the electrical connection with the corresponding second pad through the signal routing on the first copper foil layer.

In order to realize the electrical connection between first pads and second pads, a plurality of first copper foil layers 125 can be added between the blocking copper foil layer and the top copper foil layer as needed, and a second insulating layer can be added between adjacent first copper foil layers accordingly. The first pads are grouped, and the first pads of different groups are electrically connected to the corresponding second pads through the first copper foil layers and the top copper foil layer at different positions.

The interposer 100 realizes the electrical connection between the first pads and the corresponding second pads, and can be used to fan out the target signal or monitoring signal on the motherboard through the first pad to the second pad outside the molding package for testing or access to other devices.

The interposer provided in this embodiment adopts a T-shaped structure and is installed on a motherboard (such as a PCB) through a vertical body. A number of first pads with small sizes or small spacing can be fanned out and connected to second pads with large sizes or large spacing, thereby saving the space occupied by the interposer when installed on the motherboard and improving the space utilization of the motherboard.

The size of the first pad and the pad spacing can be reduced according to the SMT process capability, which can save the space occupied by the interposer on the motherboard.

In one embodiment, the height of the first insulating layer is greater than the height of the horizontal branch.

The height of the vertical body depends on the height of the first insulating layer. Increasing the height of the first insulating layer is conducive to increasing the distance between the horizontal branch and the bottom of the vertical body. When such an interposer is installed on the motherboard through the vertical body, the gap formed by the horizontal branch, the vertical body and the motherboard can be increased, thereby allowing more electronic components of different sizes to be installed in the gap.

In one embodiment of the present application, as shown in FIG. 5, a preparation method for an interposer comprises:

Step S100: manufacturing a printed circuit board (PCB) with multi layers.

As shown in FIG. 6, the PCB comprises, from bottom to top, a bottom copper foil layer 111, a first insulating layer 112, a blocking copper foil layer 121 and a top copper foil layer 123, and a second insulating layer 122 is provided between the blocking copper foil layer and the top copper foil layer; a first pad group 115 (such as the gray part comprising three first pads in FIG. 6) is provided on the bottom copper foil layer 111, and the first pad group comprises a plurality of first pads 113; a second pad group 126 (such as the gray part including three second pads in FIG. 6) corresponding to the first pad group 115 is provided on the top copper foil layer 123, and the second pad group comprises second pads 124 corresponding to the first pads one by one; the area occupied by the first pad group in the bottom copper foil layer is smaller than the area occupied by the second pad group in the top copper foil layer; a via 114 penetrating the first insulating layer 112 and the blocking copper foil layer 121 is provided at each first pad position, and the first pad 113 is electrically connected to the corresponding second pad 124 located on the top copper foil layer through the via 114.

As shown in FIG. 6, the via 114 penetrates the first insulating layer 112, the blocking copper foil layer 121 and the second insulating layer 122 to the top copper foil layer, wherein some of the first pads are directly electrically connected to the corresponding second pads through the via, and some of the first pads are electrically connected to the top copper foil layer through the via, and then electrically connected to the corresponding second pads through the signal routing.

During the PCB manufacturing process, only the first pads are left on the bottom copper foil layer, and the rest of the copper material is etched away; the top copper foil layer needs to retain the second pads and the signal routing and vias that electrically connect the first pads to the second pads, and the rest of the copper material is etched away; the first copper foil layer needs to retain the signal routing and vias that electrically connect the first pad to the second pad, and the rest of the copper material is etched away; the blocking copper foil layer needs to retain the rest of the copper material except for the via paths, so as to prevent the removal process from crossing the boundary when a portion of the first insulating layer is removed later.

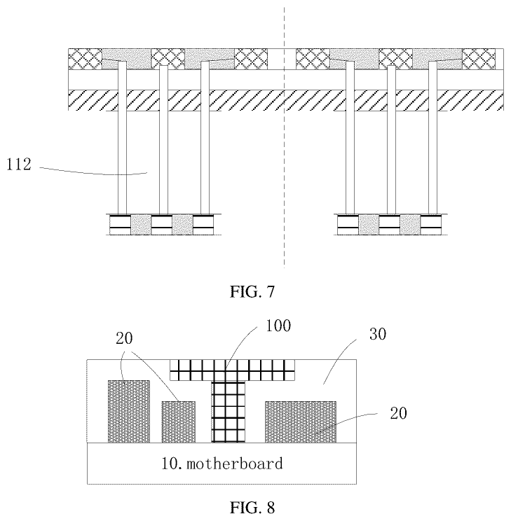

Step S200: removing the first insulating layer between adjacent first pad groups on the PCB, and the remaining first insulating layer 112 is shown in FIG. 7.

Step S300: cutting the PCB along the center line between adjacent second pad groups to obtain an interposer after cutting.

As shown in FIG. 7, the PCB is cut along the center line (the dotted line shown in FIG. 7) between adjacent second pad groups to obtain a single interposer (the structure shown in FIG. 1).

FIGS. 6-7 are only examples of the preparation of an interposer. In some embodiments, the manufactured PCB further comprises N first copper foil layers between the blocking copper foil layer and the top copper foil layer, N>=1; from the blocking copper foil layer to the top copper foil layer, second insulating layers are provided between adjacent copper foil layers. Some first pads are electrically connected to the first copper foil layer through vias, and are electrically connected to the corresponding second pads located on the top copper foil layer through the first copper foil layer.

For the first pad group consisting of the first pads in the X rows and Y columns, N first copper foil layers can be added between the blocking copper foil layer and the top copper foil layer during the preparation of the PCB, where

$$N = ⌈ \frac{min ( X , Y )}{2} ⌉ ,$$

min (X,Y) means taking the smaller value of X and Y, y indicates that ┌y┐ is rounded up. By adding N first copper foil layers, the electrical connection between the first pads and the second pads can be achieved in various situations.

The first insulating layer between adjacent first pad groups on the PCB can be removed by laser or etching, and then the PCB can be cut along the center line between adjacent second pad groups to obtain the required single interposer. When the first insulating layer is removed by laser or etching, a blocking copper foil layer is provided above the first insulating layer to prevent the removal from crossing the boundary or breaking the position.

In some embodiments, the height of the first insulating layer is greater than the height from the blocking copper foil layer to the top copper foil layer. This can increase the gap formed by the horizontal branch of the interposer and the vertical body and the motherboard after the interposer is installed on the motherboard, thereby allowing electronic components of more sizes to be installed in this gap.

In this embodiment, the interposer is prepared by adopting the design and production method of the PCB, which reduces the production cost of the interposer compared to the interposer produced by adopting the through silicon via (TSV) technology and the redistribution layer (RDL).

In one embodiment of the present application, as shown in FIG. 8, a system-in-package structure comprises:
a motherboard 10;
electronic components 20 are installed on the surface of the motherboard;
the interposer 100 described in any of the above embodiments is installed on the surface of the motherboard through its vertical body, and its horizontal branch is away from the motherboard;
the molding package 30 encapsulates the electronic components 20 and the interposer 100, and the top of the horizontal branch of the interposer 100 is exposed from the molding package.

Specifically, the motherboard can be a PCB. The interposer 100 is used to fan out the target signal or monitoring signal on the motherboard through the first pads to the second pads outside the molding package for testing or access to other devices. The interposer can be installed on the motherboard as an ordinary electronic component, such as by surface mounting technology (SMT).

Since the interposer is a T-shaped structure, the bottom area of the vertical body is smaller than the top area of the horizontal branch, and the interposer is installed on the motherboard through the vertical body, so the interposer occupies less space on the motherboard than the existing interposer.

The interposer installed on the motherboard has a horizontal branch that is away from the motherboard and extends outward from the top of the vertical body; the horizontal branch and the vertical body and the motherboard form at least one gap, and the higher the height of the vertical body, the larger the gap space formed, so that suitable electronic components can be installed under the gap.

In some embodiments, at least one electronic component is installed in at least one gap formed by the horizontal branch of the interposer and the vertical body and the motherboard, which can improve the placement rate of the motherboard and deploy more components on the motherboard. If an electronic component needs to be installed under the interposer, the electronic component can be installed first and then the interposer.

In this embodiment, the fan-out process from the motherboard to the outside of the molding package can be completed by adopting a T-shaped integrated interposer, and at the same time, the layout space of the motherboard can be effectively saved, the space utilization rate of the motherboard can be improved, and more components can be deployed on the motherboard.

It should be noted that the above embodiments can be freely combined as needed. The above are only preferred embodiments of the present application. It should be pointed out, that for ordinary skilled in the art, several improvements and modifications can be made without departing from the principle of the present application, and these improvements and modifications should also be regarded as within the protection scope of the present application.

1. An interposer, characterized by comprising:
a vertical body and a horizontal branch, wherein the horizontal branch extends outward from a top of the vertical body; the top of the vertical body contacts a bottom of the horizontal branch to form a T-shaped structure;
the vertical body comprises a bottom copper foil layer and a first insulating layer in order from bottom to top, and a plurality of first pads are provided on the bottom copper foil layer;
the horizontal branch comprises a blocking copper foil layer, a second insulating layer and a top copper foil layer in order from bottom to top; the top copper foil layer is provided with second pads corresponding to the first pads one by one; an area of a bottom of the vertical body is smaller than an area of a top of the horizontal branch;
a via penetrating the first insulating layer and the blocking copper foil layer is provided at each first pad position, and one first pad is electrically connected to one corresponding second pad located on the top copper foil layer through the via.

2. The interposer according to claim 1, characterized in that:
the horizontal branch further comprises N first copper foil layers between the blocking copper foil layer and the top copper foil layer, where N>=1; and second insulating layers are provided between adjacent copper foil layers from the blocking copper foil layer to the top copper foil layer;
said one first pad is electrically connected to one corresponding second pad located on the top copper foil layer through the via, comprises:
the first pad is electrically connected to the first copper foil layer through the via, and is electrically connected to the corresponding second pad located on the top copper foil layer through the first copper foil layer.

3. The interposer according to claim 1, characterized in that:
a height of the first insulating layer is greater than a height of the horizontal branch.

4. A preparation method for an interposer, characterized by comprising:
manufacturing a PCB with multi layers, wherein the PCB comprises, from bottom to top, a bottom copper foil layer, a first insulating layer, a blocking copper foil layer and a top copper foil layer, wherein a second insulating layer is provided between the blocking copper foil layer and the top copper foil layer; a plurality of first pad groups are provided on the bottom copper foil layer, wherein the first pad group comprises a plurality of first pads; a plurality of second pad groups corresponding to the first pad groups are provided on the top copper foil layer, wherein the second pad group comprises second pads corresponding to the first pads one by one;
an area of the first pad group is smaller than an area of the second pad group; a via penetrating the first insulating layer and the blocking copper foil layer is provided at each first pad position, wherein one first pad is electrically connected to one corresponding second pad located on the top copper foil layer through the via;
removing the first insulating layer between adjacent first pad groups on the PCB;
cutting the PCB along a center line between adjacent second pad groups to obtain an interposer after cutting.

5. The preparation method according to claim 4, characterized in that the step of one first pad is electrically connected to one corresponding second pad located on the top copper foil layer through the via, comprises:
the first pad is electrically connected to the top copper foil layer through the via, and is electrically connected to the corresponding second pad located on the top copper foil layer through the top copper foil layer.

6. The preparation method according to claim 4, characterized in that:
the PCB further comprises N first copper foil layers between the blocking copper foil layer and the top copper foil layer, where N>=1; and second insulating layers are provided between adjacent copper foil layers from the blocking copper foil layer to the top copper foil layer;
the step of one first pad is electrically connected to one corresponding second pad located on the top copper foil layer through the via, comprises:
the first pad is electrically connected to the top copper foil layer through the via, and is electrically connected to the corresponding second pad located on the top copper foil layer through the top copper foil layer.

7. The preparation method according to claim 6, characterized in that:
the first pad group is composed of first pads in X rows and Y columns;
the PCB further comprises N first copper foil layers between the blocking copper foil layer and the top copper foil layer, wherein N is equal to a result of rounding up a quotient obtained by dividing a minimum value of X and Y by 2.

8. The preparation method according to claim 4, characterized in that:
removing the first insulating layer between adjacent first pad groups on the PCB by laser or etching.

9. A system-in-package structure, characterized by comprising:
a motherboard;
electronic components, which are installed on a surface of the motherboard;
an interposer according to claim 1 is installed on the surface of the motherboard through its vertical body;
a molding package, which encapsulates the electronic components and the interposer, and a top of a horizontal branch of the interposer is exposed from the molding package.

10. The system-in-package structure according to claim 9, characterized in that:
at least one electronic component is installed in at least one gap formed by the horizontal branch of the interposer, the vertical body and the motherboard.

11. The system-in-package structure according to claim 10, characterized in that:
the electronic components are installed first and then the interposer if the electronic components are installed under the interposer.

12. The system-in-package structure according to claim 9, characterized in that:
the interposer is installed on the surface of the motherboard through its vertical body by surface mounting technology.

13. A system-in-package structure, characterized by comprising:
a motherboard;
electronic components, which are installed on a surface of the motherboard;
an interposer according to claim 2 is installed on the surface of the motherboard through its vertical body;
a molding package, which encapsulates the electronic components and the interposer, and a top of a horizontal branch of the interposer is exposed from the molding package.

14. The system-in-package structure according to claim 13, characterized in that:
at least one electronic component is installed in at least one gap formed by the horizontal branch of the interposer, the vertical body and the motherboard.

15. The system-in-package structure according to claim 14, characterized in that:
the electronic components are installed first and then the interposer if the electronic components are installed under the interposer.

16. The system-in-package structure according to claim 13, characterized in that:
the interposer is installed on the surface of the motherboard through its vertical body by surface mounting technology.

17. A system-in-package structure, characterized by comprising:
a motherboard;
electronic components, which are installed on a surface of the motherboard;
an interposer according to claim 3 is installed on the surface of the motherboard through its vertical body;
a molding package, which encapsulates the electronic components and the interposer, and a top of a horizontal branch of the interposer is exposed from the molding package.

18. The system-in-package structure according to claim 17, characterized in that:
at least one electronic component is installed in at least one gap formed by the horizontal branch of the interposer, the vertical body and the motherboard.

19. The system-in-package structure according to claim 18, characterized in the electronic components are installed first and then the interposer if the electronic components are installed under the interposer.

20. The system-in-package structure according to claim 17, characterized in that:
the interposer is installed on the surface of the motherboard through its vertical body by surface mounting technology.
